(19) United States
(12) Patent Application Publication
(10) Pub. No.: US 2012/0214316 A1
(43) Pub. Date: Aug. 23, 2012

(54) SEMICONDUCTOR DEVICES HAVING PLANARIZED INSULATION LAYERS AND METHODS OF FABRICATING THE SAME

(76) Inventors: Jin-Woo Bae, Yongin-si (KR); Inseak Hwang, Suwon-si (KR); Myangsik Han, Suwon-si (KR); Se Jung Park, Suwon-si (KR); Sung-Min Cho, Goyang-si (KR); YoungHo Koh, Seongnam-si (KR); Yi Koan Hong, Suwon-si (KR)

(21) Appl. No.: 13/398,895

(22) Filed: Feb. 17, 2012

(30) Foreign Application Priority Data
Feb. 21, 2011 (KR) 10-2011-0015165

(51) Int. Cl. H01L 21/31

(52) U.S. Cl. 438/763; 257/E21.24

(57) ABSTRACT

A semiconductor device and a method of fabricating a semiconductor device including a step of providing a substrate having a first region and a second region adjacent to each other, a step of forming a structure on the substrate in the first region, the structure including a top surface and a sidewall, a step of forming a first insulation layer on the substrate including the structure, the first insulation layer including a first top surface in the first region, an inclined sidewall on the sidewall of structure, and a second top surface in the second region, a step of forming a second insulation layer on the first insulation layer, and a step of planarizing the second and first insulation layers to form a common planarized surface.

### CROSS-REFERENCE TO RELATED APPLICATIONS

This U.S. non-provisional patent application claims priority under 35 U.S.C. §119 to Korean Patent Application No. 10-2011-0015165, filed on Feb. 21, 2011, the entirety of which is incorporated by reference herein.

### TECHNICAL FIELD

The present disclosure herein relates to semiconductor devices and methods of fabricating the same and, more particularly, to semiconductor devices having planarized insulation layers and methods of fabricating the same.

### DESCRIPTION OF RELATED ART

As the height of the data storage elements of semiconductor memory devices increases, a step height also increases between the cell array region and the peripheral circuit region. For subsequent processes, the step height should be eliminated by a planarizing process. During a planarization process, a pressure may be applied to a substrate so that the pressure can concentrate to cause crack on weak portion of the substrate. Therefore, a device structure is required to immune from such stress concentration.

### SUMMARY

In an embodiment of the inventive concept, a method of fabricating a semiconductor device comprises a step of providing a substrate having a first region and a second region adjacent to each other, a step of forming a structure on the substrate in the first region, the structure including a top surface and a sidewall, a step of forming a first insulation layer on the substrate including the structure, the first insulation layer including a first top surface in the first region, an inclined sidewall on the sidewall of structure, and a second top surface in the second region, a step of forming a second insulation layer on the first insulation layer, and a step of planarizing the second and first insulation layers to form a common planarized surface.

The structure is formed to include data storage elements. The first insulation layer is formed of a silicon oxide layer using a chemical vapor deposition (CVD) technique. The first insulation layer is formed using a tetra-ethyl-ortho-silicate (TEOS) as a silicon source. The second insulation layer is formed of a silicon oxide layer different from the first insulation layer.

The second insulation layer is formed of a high density plasma (HDP) oxide layer or a boro-phospho-silicate glass (BPSG) layer.

The step of planarizing the second and first insulation layers is performed using a chemical mechanical polishing (CMP) technique. The second top surface of the first insulation layer is lower than the top surface of the structure. The common planarized surface include a first planarized surface of the first insulation layer and a second planarized surface of the second insulation layer, wherein the first planarized surface is located over the first and second regions and the second planarized surface is located over the second region. The first planarized surface is substantially coplanar with the second planarized surface.

In another embodiment of the inventive concept, a semiconductor device comprises a substrate having a first region and a second region adjacent to each other, a structure on the substrate in the first region, the structure having a top surface and a sidewall, a first planarized insulation layer on the structure and the second region; and a second planarized insulation layer on the first planarized insulation layer in the second region.

The structure includes data storage elements. A top surface of the first planarized insulation layer in the second region has the same level as or a lower level than the top surface of the structure. The first planarized insulation layer includes a first CVD oxide layer, and wherein the second planarized insulation layer includes a second CVD oxide layer different from the first CVD oxide layer. The first CVD oxide layer includes a tetra-ethyl-ortho-silicate (TEOS) oxide layer, and wherein the second CVD oxide layer includes a high density plasma (HDP) oxide layer or a boro-phospho-silicate glass (BPSG) layer. A top surface of the first planarized insulation layer in the first region is coplanar with a top surface of the second planarized insulation layer in the second region.

In yet another embodiment of the inventive concept, a semiconductor device comprises a substrate having a first region and a second region, a structure disposed on the first region, the structure having a top surface higher than the substrate of the second region, and the structure further having a sidewall meeting the substrate at a right angle, a first planarized insulation layer on the structure and the substrate, and a second planarized insulation layer on the first planarized insulation layer in the second region.

The first planarized insulation layer includes a TEOS CVD oxide layer, and wherein the second planarized insulation layer includes a high density plasma (HDP) oxide layer or a boro-phospho-silicate glass (BPSG) layer. The structure includes data storage elements and the second region includes a peripheral circuit. The structure includes data storage elements and the second region includes a peripheral circuit. The first planarized insulation layer is substantially coplanar with the second planarized insulation layer.

### BRIEF DESCRIPTION OF THE DRAWINGS

The inventive concept will become more apparent in view of the attached drawings and accompanying detailed description.

FIGS. 1 to 4 are cross sectional views illustrating methods of fabricating a semiconductor device according to an embodiment of the inventive concept and the related semiconductor device.

### DETAILED DESCRIPTION OF THE EMBODIMENTS

The inventive concept will now be described more fully hereinafter with reference to the accompanying drawings, in which preferred embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity. Furthermore, the same reference numerals denote the same elements throughout the specification.

As used herein, the term “and/or” includes any and all combinations of one or more of the associated listed items. It will be understood that when an element is referred to as being “connected” or “coupled” to another element, it may be directly connected or coupled to the other element or intervening elements may be present. Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. Like reference numerals refer to like elements throughout the specification.

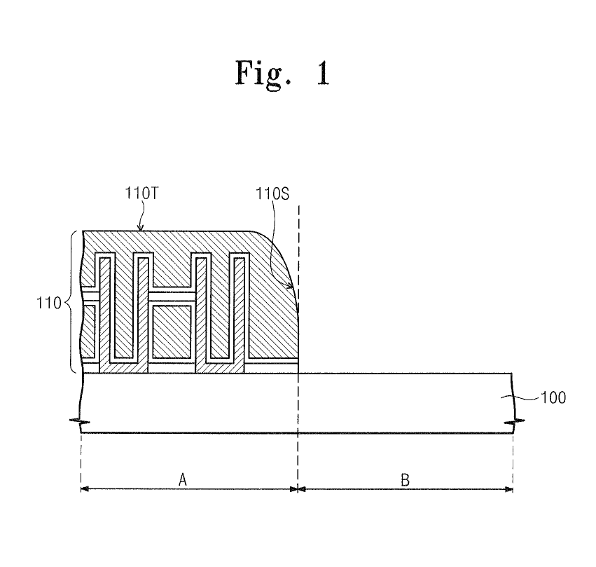

FIGS. 1 to 4 are cross sectional views illustrating methods of fabricating a semiconductor device according to an embodiment of the inventive concept and the related semiconductor device.

Referring to FIG. 1, a substrate 100 having first and second regions A and B adjacent to each other may be prepared. The substrate 100 may include a semiconductor substrate such as a silicon substrate. In an embodiment, the first region A may correspond to a cell array region, and the second region B may correspond to a peripheral circuit region. A structure 110 may be formed on the substrate 100 in the first region A. A top surface 110T of the structure 110 may be higher than a top surface of the second region B of the substrate 100. Thus, there may be a step difference or a step height at an interface region between the first and second regions A and B. The structure 110 may be formed to include data storage elements. The data storage elements may include DRAM cells, resistive memory cells, static random access memory (SRAM) cells and/or flash memory cells.

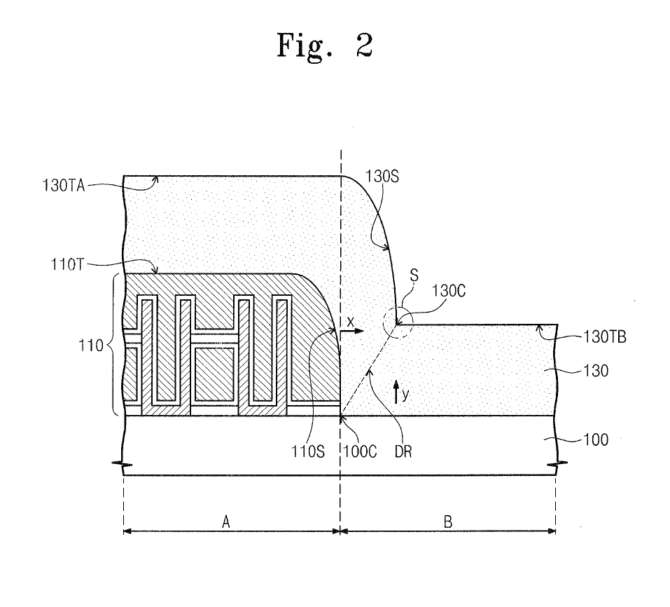

Referring to FIG. 2, a first insulation layer 130 may be formed on the substrate including the structure 110. The first insulation layer 130 may be conformally formed. The first insulation layer 130 may be formed to include a first top surface 130TA in the first region A, an inclined sidewall 130S over a sidewall 1105 of the structure 110, and a second top surface 130TB in the second region B. In an embodiment, the first insulation layer 130 may be formed so that the second top surface 130TB in the second region B has the same level as or a lower level than the top surface 110T of the structure 110 in the first region A. Alternatively, the first insulation layer 130 may be formed so that the second top surface 130TB in the second region B has a higher level than the top surface 110T of the structure 110 in the first region A.

The first insulation layer 130 may be formed of a silicon oxide layer. For example, the first insulation layer 130 may be formed of a tetra-ethyl-ortho-silicate (TEOS) layer. The TEOS layer may be formed using a tetra-ethyl-ortho-silicate (TEOS) as a silicon source. Further, the first insulation layer 130 may be formed using a chemical vapor deposition (CVD) technique. In this case, the first insulation layer 130 formed on the sidewall 110S of the structure 110 may be deposited in an X direction parallel to the top surface of the substrate 100, and the first insulation layer 130 formed on the substrate 100 in the second region B may be deposited in a Y direction perpendicular to the top surface of the substrate 100. Thus, a discontinuous region DR may be formed at a region located between a first position 100C and a second position 130C. The first position may be a position where the sidewall 110S of the structure 110 meets the top surface of the substrate 100 at a right angle each other. The second position 130C may be a position where the inclined sidewall 130S of the first insulation layer 130 meets the top surface 130TB of the first insulation layer 130 in the second region B each other.

The discontinuous region DR may not be continuous in crystallography. Thus, the discontinuous region DR may exhibits a relatively weak bonding energy.

While the first insulation layer 130 is polished by a chemical mechanical polishing (CMP) technique, a physical stress may be concentrated on the discontinuous region DR. In particular, when the first insulation layer 130 is formed of a TEOS layer and the TEOS layer is directly planarized using the CMP technique, a stress concentration region S including the second position 130C may be detached from the TEOS layer 130. As a result, dent regions, which are irregularly recessed, may be formed at a surface of the planarized TEOS layer 130. Moreover, in the event that the first insulation layer 130 is directly planarized using the CMP technique, cracks may be formed along the discontinuous region DR. Thus, the embodiments of the inventive concept may preclude directly planarizing the first insulation layer 130 using the CMP technique.

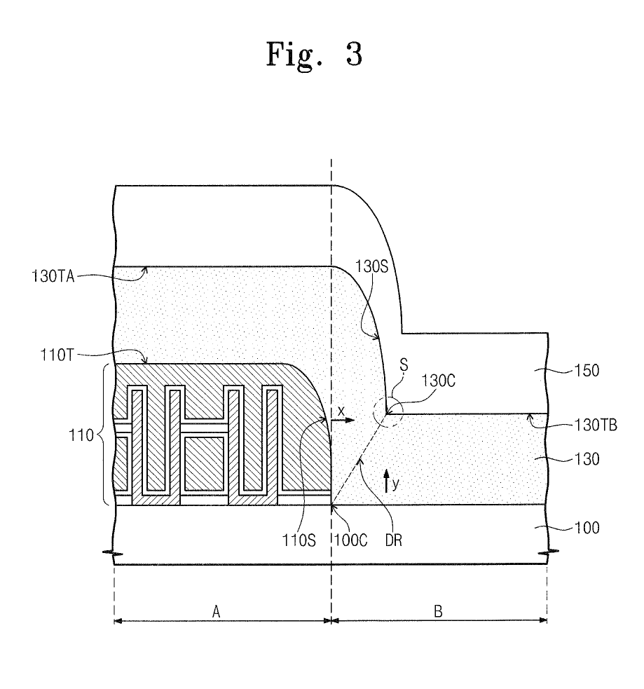

Referring to FIG. 3, a second insulation layer 150 may be formed on the first insulation layer 130. The second insulation layer 150 may be formed so that a flat top surface of the second insulation layer 150 in the second region B has a higher level than a top surface 110T of the structure 110 in the first region A. In another embodiment, the second insulation layer 150 may be formed so that a flat top surface of the second insulation layer 150 in the second region B has the same level as or a lower level than a top surface 110T of the structure 110 in the first region A.

The second insulation layer 150 may be formed of a silicon oxide layer which is different from the first insulation layer 130. For example, the first insulation layer 130 may be formed of a first CVD oxide layer and the second insulation layer 150 may be formed of a second CVD oxide layer different from the first CVD oxide layer. In an embodiment, when the first insulation layer 130 is formed of a TEOS layer, the second insulation layer 150 may be formed of a high density plasma (HDP) oxide layer or a boro-phospho-silicate glass (BPSG) layer.

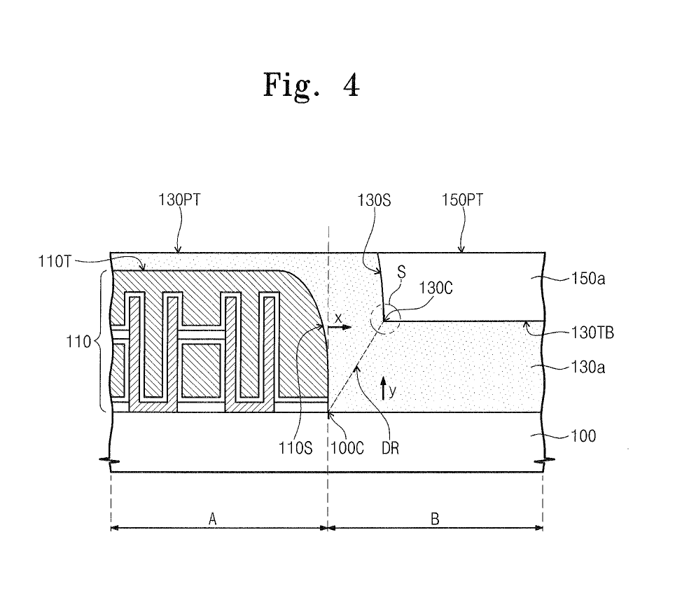

Referring to FIG. 4, the first and second insulation layers 130 and 150 may be planarized to form a first planarized insulation layer 130a remained in the second region B and a second planarized insulation layer 150a existing on the first planarized insulation layer 130a. The planarization process may be performed so that at least the stress concentration region S of the first planarized insulation layer 130a is covered with the second planarized insulation layer 150a.

The planarization of the first and second insulation layers 130 and 150 may be performed using the CMP technique. The CMP technique may correspond to a polishing method which uses a self-stop slurry. The self-stop slurry may have a function that removes a surface step difference in response to a pressure during a polishing process. The planarization process may be performed so that a portion of the first insulation layer 130 remains in the first region A. That is, the planarization process may be ended before the structure 110 is exposed.

If the first insulation layer 130 is directly planarized without formation of the second insulation layer 150, dent regions may be formed at a surface of the first insulation layer 130 and/or cracks may be formed in the first insulation layer 130 as described with reference to FIG. 2. These dent regions and/or the cracks may cause electrical shortages between contact plugs to be formed in the first planarized insulation layer 130a in a subsequent process. However, according to the embodiments of the inventive concept, the first and second insulation layers 130 and 150 may be planarized after the second insulation layer 150 is formed on the first insulation layer 130. In this case, the second insulation layer 150 may act as a stress buffer layer that alleviates a physical stress which is applied to the stress concentration region S of the first insulation layer 130 during the planarization process. Thus, the embodiments of the inventive concept may prevent the dent regions and the cracks from being formed in the first and second planarized insulation layers 130a and 150a.

Now, semiconductor devices according to embodiments of the inventive concept will be described with reference to FIG. 4.

Referring again to FIG. 4, a substrate 100 having first and second regions A and B adjacent to each other may be provided. The substrate 100 may include a semiconductor substrate such as a silicon substrate. A structure 110 may be disposed on the substrate 100 in the first region A. The structure 110 may have a top surface 110T and a sidewall 110S. The structure 110 may include data storage elements. For example, the data storage elements may include DRAM cells, SRAM cells, resistive memory cells and/or flash memory cells.

A planarized insulation layer may be disposed on the substrate including the structure 110. The planarized insulation layer may include a first planarized insulation layer 130a on the substrate having the structure 110 and a second planarized insulation layer 150a covering the first planarized insulation layer 130a in the second region B.

A discontinuous region DR may be disposed to extend from a first position 100C that a sidewall 110S of the structure 110 and a top surface of the substrate 100 contact each other to a second position 130C that an inclined sidewall 130S of the first planarized insulation layer 130a and a top surface 130TB of the first planarized insulation layer 130a in the second region B contact each other.

A stress concentration region S may be located at the second, position 130C that the inclined sidewall 130S of the first planarized insulation layer 130a and the top surface 130TB of the first planarized insulation layer 130a are in contact with each other.

In the second region B, a portion of the second planarized insulation layer 150a may cover the stress concentration region S. A top surface 130TB of the first planarized insulation layer 130a in the second region B may have the same level as or a lower level than a top surface 110T of the structure 110. Alternatively, The top surface 130TB of the first planarized insulation layer 130a in the second region B may have a higher level than the top surface 110T of the structure 110.

The first planarized insulation layer 130a may include a first CVD oxide layer, and the second planarized insulation layer 150a may include a second CVD oxide layer different from the first CVD oxide layer. In an embodiment, when the first planarized insulation layer 130a includes a TEOS layer, the second planarized insulation layer 150a may include a HDP oxide layer or a BPSG layer.

A top surface 130PT of the first planarized insulation layer 130a in the first region A may have the same level as a top surface 150PT of the second planarized insulation layer 150a in the second region B. That is, the top surface 130PT of the first planarized insulation layer 130a in the first region A may be coplanar with the top surface 150PT of the second planarized insulation layer 150a in the second region B.

According to the embodiments set forth above, a first insulation layer and a second insulation layer may be sequentially formed on a substrate having a step difference, and the first and second insulation layers may be planarized. The planarization may be performed so that a stress concentration region adjacent to a step difference region of the first insulation layer is covered with a portion of the second insulation layer. Thus, the second insulation layer may prevent a physical stress from being applied to the stress concentration region of the first insulation layer during the planarization. As a result, it may suppress generation of defects in the first and second planarized insulation layers.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A method of fabricating a semiconductor device, the method comprising steps of:
providing a substrate having a first region and a second region adjacent to each other;
forming a structure on the substrate in the first region, the structure including a top surface and a sidewall;
forming a first insulation layer on the substrate including the structure, the first insulation layer including a first top surface in the first region, an inclined sidewall on the sidewall of structure, and a second top surface in the second region;
forming a second insulation layer on the first insulation layer; and
planarizing the second and first insulation layers to form a common planarized surface.

2. The method of claim 1, wherein the structure is formed to include data storage elements.

3. The method of claim 1, wherein the first insulation layer is formed of a silicon oxide layer using a chemical vapor deposition (CVD) technique.

4. The method of claim 3, wherein the first insulation layer is formed using a tetra-ethyl-ortho-silicate (TEOS) as a silicon source.

5. The method of claim 3, wherein the second insulation layer is formed of a silicon oxide layer different from the first insulation layer.

6. The method of claim 5, wherein the second insulation layer is formed of a high density plasma (HDP) oxide layer or a boro-phospho-silicate glass (BPSG) layer.

7. The method of claim 1, wherein the step of planarizing the second and first insulation layers is performed using a chemical mechanical polishing (CMP) technique.

8. The method of claim 1, wherein the second top surface of the first insulation layer is lower than the top surface of the structure.

9. The method of claim 1, wherein the common planarized surface include a first planarized surface of the first insulation layer and a second planarized surface of the second insulation layer, wherein the first planarized surface is located over the first and second regions and the second planarized surface is located over the second region.

10. The method of claim 9, wherein the first planarized surface is substantially coplanar with the second planarized surface.

11-20. (canceled)
